(19) United States
(12) Patent Application Publication
(10) Pub. No.: US 2006/0215373 A1
(43) Pub. Date: Sep. 28, 2006

(54) Device for levering in and levering out a plug-in unit

(75) Inventors: Michael Joist, Gaggenau (DE); Paul Rutherford, Karlsruhe (DE); Heinz Euchner, Birkenfeld (DE); Klaus-Michael Thalau, Malsch (DE)

Correspondence Address: VENABLE LLP, P.O. BOX 34385, WASHINGTON, DC, 20045-9998, US

(73) Assignee: Schroff GmbH, Straubenhardt (DE)

(21) Appl. No.: 11/372,234

(22) Filed: Mar. 10, 2006

(30) Foreign Application Priority Data
Mar. 10, 2005 (DE) 20 2005 004 039.8
Apr. 8, 2005 (EP) 05 007 706.4

(51) Int. Cl. H05K 7/16

(52) U.S. Cl. 361/726

(57) ABSTRACT

A device for levering in and levering out a plug-in unit into and out of a module carrier includes a corner piece adapted for being arranged in a frontal region of the plug-in unit, and a pull lever comprising. The pull lever includes a lever positioned to be pivotable on the corner piece. The lever has a long lever arm and a short lever arm that is adapted to be supported on a lateral profile of the module carrier. The pull lever further includes a handle rotatably positioned on the long lever arm of the lever. The handle is arranged to be displaceable in a longitudinal direction between a starting position in which the handle is freely rotatable, and an engaged position in which the handle is connected force-locking with the long lever arm for pivoting the lever.

### CROSS-REFERENCE TO RELATED APPLICATION

This application claims the priority of German Application DE 20 2005 004 039.8 filed on Mar. 10, 2005 and European Patent Application No. EP 05 007 706.4, filed on Apr. 8, 2005, the subject matter of which is incorporated herein by reference.

### BACKGROUND OF THE INVENTION

The invention relates to a device for levering in and levering out a plug-in unit into and out of a module carrier. Such a device comprises a corner piece arranged in a frontal region of the plug-in unit and a lever pull handle with a lever that is pivotally positioned on the corner piece, wherein a short lever arm is supported on a lateral profile of the module carrier and a grip is positioned rotating on a long lever arm.

With electronic equipment having a modular configuration, it is presently standard procedure to design the individual electronic modules as plug-in units. A plug-in unit of this type is provided with a multi-pole connector at the back end, which is plugged into a corresponding multipoint connector strip on the motherboard, the so-called back plane, of the module carrier. To create as well as separate the plug-in connection, considerable mechanical forces must be overcome, which depend on the type of connector used and in particular on the number of contacts. With electromagnetically screened plug-in units, the frictional forces of the EMV [electromagnetic compatibility] seals between the individual plug-in units and/or the plug-in unit and the module carrier must furthermore be overcome.

At least one pull lever is provided in the frontal region of the plug-in unit to overcome these forces during the insertion and removal of the plug-in unit. With the aid of this lever, the plug-in unit can be levered in or levered out of the module carrier.

If the plug-in unit forms a component of a bus system, a micro-switch is simultaneously activated during the levering in or levering out, wherein this micro-switch activates or cuts off the current supply. The electronic module can therefore be installed or removed during the operation. This so-called hot-swap-function is listed in the specification for numerous modular systems, for example those used in telecommunications.

Furthermore specified or at least desired is a mechanical lock for the pull lever to prevent the accidental levering out and thus a separation of the plug-in module from the bus system.

Pull levers levering in and levering out a plug-in unit, with and without automatic active-passive switching and/or locking device, are available in many different designs. Depending on the type of use, these pull levers differ with respect to angle of rotation, displacement, translation ratio, mode of operation, and optical appearance.

European patent document EP 1 499 171 A1 discloses a device for levering in and levering out a plug-in unit, for which a locking lever is rotatably attached to the handle arm of the lever pull and functions to block the pivoting motion of the pull lever.

A similar pull lever is disclosed in European patent document EP 1 463 394 A1, wherein the lever arm of the pull lever is provided with a switch lever with a rotatably attached pawl which can activate a micro-switch once the plug-in unit is completely inserted. The pawl for the switch lever furthermore has a detent nose, which can engage behind a detent edge in the frontal region of the plug-in unit to prevent a pivoting of the pull lever.

U.S. Pat. No. 6,685,489 B1 and the associated unexamined, published, German patent application DE 103 27 948 A1 disclose a lever mechanism for switchboards, having a toothed gearing.

German patent document DE 41 05 948 A1 describes a device for levering in and levering out a plug-in unit from a module carrier, comprising a cooling body arranged in the frontal region of the plug-in unit, a pull lever with a lever that is positioned pivoting on the cooling body and for which the short lever arm is supported on a lateral profile of the module carrier, as well as an activation arm that is positioned rotating on the long lever arm and has an exposed end which is embodied as a grip. The activation arm can be folded out, to an end stop predetermined by the upper edge of the lever. As a result, a wire spring that functions as a locking mechanism is guided out of a recess in the long lever arm.

The present application specifically relates to pull levers for modern telecommunications systems based on the ATCA Standard (Advanced Telecom Computing Architecture) developed by PICMIG (PCI Industrial Computing Manufactory Group). This standard specifies that the rotational movement of the pull lever should be 75°. At the same time, an upper and a lower horizontal limiting line is predetermined for the rotational movement of the grip, wherein the upper limiting line is intended to make possible the installation of a sub-module, a so-called AMC (advance mezzanine card module) just above the corner piece of the plug-in unit. The lower limiting line is intended to prevent a collision between the pull lever and components below the plug-in unit, such as a cable trough.

### SUMMARY OF THE INVENTION

It is therefore an object of the present invention to design a pull lever for electronic plug-in units so that the region to be kept clear for pivoting the pull lever, meaning the region above and below the pivoting axis, is kept as narrow as possible, in particular within an upper and lower limiting line parallel to the insertion direction while still maintaining for the most part the standard lever geometry and an unchanged, high lever effect.

The above and other objects are accomplished according to the invention by the provision of a device for levering in and levering out a plug-in unit into and out of a module carrier, which in an exemplary embodiment includes: a corner piece adapted for being arranged in a frontal region of the plug-in unit; and a pull lever comprising: a lever positioned to be pivotable on the corner piece, the lever including a long lever arm and a short lever arm that is adapted to be supported on a lateral profile of the module carrier, and a handle rotatably positioned on the long lever arm of the lever; wherein the handle is arranged to be displaceable in a longitudinal direction between a starting position in which the handle is freely rotatable, and an engaged position in which the handle is connected force-locking with the long lever arm for pivoting the lever.

Thus, according to the invention, the long lever arm has a two-part design, wherein the handle is attached articulated to the long lever arm, thereby permitting a pivoting of the handle in different angle positions, relative to the lever arm. As a result, the height-restricted space for pivoting can be used in multiple ways. The handle is furthermore positioned on the lever arm so that it can be displaced in a longitudinal direction. The handle consequently can be moved back and forth easily between a starting position, in which it can turn freely relative to the lever arm, and an engaged position, in which a gripping piece is fixedly connected to the lever arm.

For example, the handle can initially be moved into a horizontal position and can then be connected force-locking with the lever arm. Following a specific pivoting of the lever, the force-locking connection to the handle is released and the handle is turned counter to the rotational direction of the lever and is then again connected force-locking with the lever arm. The longer the handle and the tighter the limitation of the pivoting range, the more often the handle must be shifted until the lever is moved to its end position and the plug-in unit is completely levered out.

One considerable advantage of the pull lever is that the standardized geometry of the lever itself is not changed, in particular the standard angle of rotation of approximately 75° is maintained, even though the handle is rotated only by a maximum angle of 45°, for example, relative to the horizontal line.

U.S. Pat. No. 4,530,262 discloses an open-ended wrench with two arms, joined by a rotating joint. The rotating joint comprises an axially displaceable, toothed wheel with locking pin, which can be activated from the outside. If the toothed wheel is in the one end position, the arms can be rotated in opposite directions to permit adjusting their angle position relative to each other. By pressing against the locking pin, the toothed wheel is then moved to the other end position, thereby locking the rotating joint in place so that a torque can be transferred from one arm to the other arm. To be sure, the two arms of the open-ended wrench can be rotated around a joint axis, but they cannot be displaced relative to each other in the longitudinal direction.

Published European patent application EP 0 377 777 A1 describes a ratchet, consisting of a handle bar with manual grip and an operating head with a square socket that functions as ratchet. The handle bar can be placed at an angle relative to the operating head, and in the angled position can be locked in placed with a manually displaceable locking bar that is arranged inside the handle bar. The angling plane extends perpendicular to the rotational plane for the ratchet. To be sure, the handle bar can be angled, but cannot be rotated relative to the operating head. The transfer of a torque from the handle piece to the operating head is independent of the angle position of the handle piece. The displaceable locking bar in the handle bar only functions to lock the handle in place in the angled position and not to separate the force-locking connection between handle bar and operating head.

A displacement in the longitudinal direction can be achieved through simple structural means, for example by providing the handle with an elongated hole and providing a bearing shaft on the long lever arm, which engages in the elongated hole in the handle. Of course, the elongated hole can also be provided on the lever arm and the bearing shaft can be provided on the handle. If the handle is displaced in the longitudinal direction, the bearing shaft changes from one end of the elongated hole to the other end, wherein the length of the elongated hole restricts the displacement. In the process, the handle can be held by means of a spring in the starting position in which it can turn freely. The handle is then pushed forward, counter to the spring effect, meaning in the direction of the front panel and the engaged position, so as to create a force-locking connection with the lever arm.

According to one exemplary embodiment of the invention, the handle can be connected force-locking with the lever arm only when it is in specifically selected angle positions. The number and location of these angle positions depend on the limiting lines for the region in which the handle is allowed to move. When using an easily moved handle of average length, for example, it is sufficient to use three different angle positions to completely lever in or lever out the plug-in unit.

According to one advantageous and useful modification of the invention, the handle and the long arm of the lever are provided with means, allocated to each other, for creating a form-locking connection, wherein this form-locking connection is created as soon as the handle is in the engaged position. The long lever arm can be provided with a rocking-arm guide, for example, in which a pusher for the handle engages. A few selected angle positions can be predetermined by such a rocking-arm guide, in which the handle permits a force transmission to the lever arm through a form-locking connection. One of the angle positions for the handle, made possible by the rocking-arm guide, e.g. the horizontal position, can be used for locking and unlocking the lever. The same angle position can simultaneously also be used for the active and passive switching of the electronic module by depressing the handle. Two additional angle positions can additionally be specified, for example, which are used only for pivoting the lever.

To easily move to the selected angle position, the long lever arm and the handle can be provided with corresponding locking means that secure the handle in the specified angle positions. For this, at least some of the angle positions, which are predetermined by the locking means, correspond to the selected angle positions in which the handle can be connected form-locking with the lever arm. Additional angle positions for the handle can be predetermined, in which no form-locking connection with the lever arm is possible, for example various resting positions.

A different advantageous embodiment of the invention includes a push rod, positioned on the end piece of the plug-in unit so as to be displaceable in the longitudinal direction, wherein this push rod locks the lever in place to prevent pivoting. The push rod can be moved by the handle from the locked position to an unlocked position, provided the handle is in one of the selected angle positions. An automatic unlocking of the pull lever is thus possible immediately prior to the first pivoting of the lever, while an unintended unlocking is simultaneously prevented. The push rod returns to the locked position once the plug-in unit is completed levered in.

The push rod can furthermore operate a micro-switch for the active and passive switching of the plug-in unit. Normally, meaning when the plug-in unit is fully inserted, the micro-switch is in the ON position. The micro-switch is in the OFF position when the power to the plug-in unit is disconnected, as soon as the handle is in a selected angle position where it is connected force-locking and/or form-locking with the lever and the push rod is consequently displaced toward the back.

The automatic locking in place of the pull lever with simultaneous activation of the plug-in unit, following the complete levering in, can be achieved easily when the pull rod is pulled by a spring in the direction of the front panel of the plug-in unit. As soon as the handle returns from its engaged position to the starting position, the push rod follows under the effect of the spring, thereby locking the lever arm in place against pivoting and moving the micro-switch to the ON position.

### BRIEF DESCRIPTION OF THE DRAWINGS

These and other features and advantages of the invention will be further understood from the following detailed description of the exemplary embodiments with reference to the accompanying drawings.

FIGS. 1a, 1b show two perspective views of the front lower edge of a plug-in unit with attached pull lever, at an angle from above and at an angle from below.

FIGS. 2a, 2b show the lever portion of the pull lever;

FIGS. 3a, 3b show the handle portion of the pull lever.

FIGS. 4a, 4b show the push rod for the pull lever.

FIG. 5 shows a partial sectional view of the pull lever with lever portion, handle, and front end of the push rod.

FIGS. 6a, 6b show the plug-in unit, completely levered into a module carrier, shown in a partial sectional view;

FIGS. 7a, 7b show the start of the operation for levering out the plug-in unit.

FIGS. 8a, 8b show the partially levered-out plug-in unit.

FIGS. 9a-9d show the plug-in unit at a further stage of levering it out.

FIGS. 10a, 10b show the completely levered-out plug-in unit.

### DETAILED DESCRIPTION OF THE INVENTION

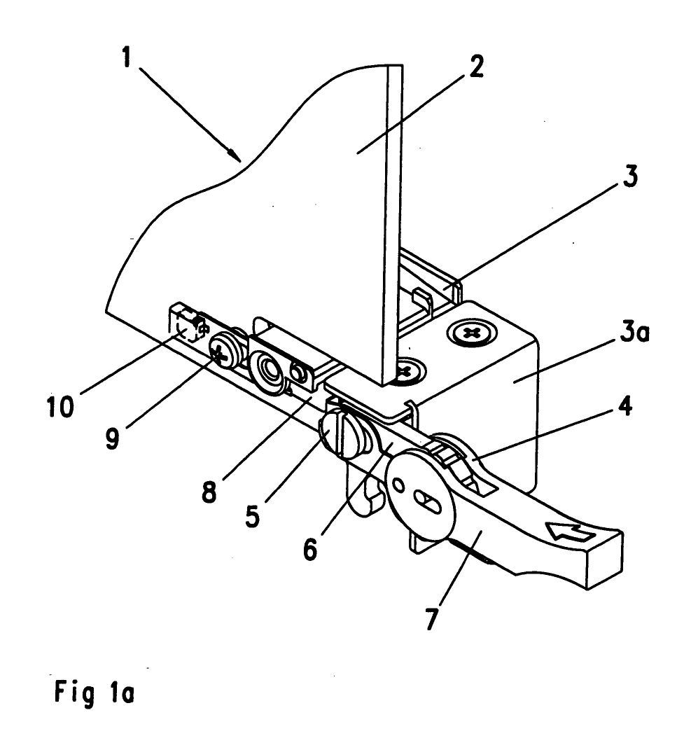

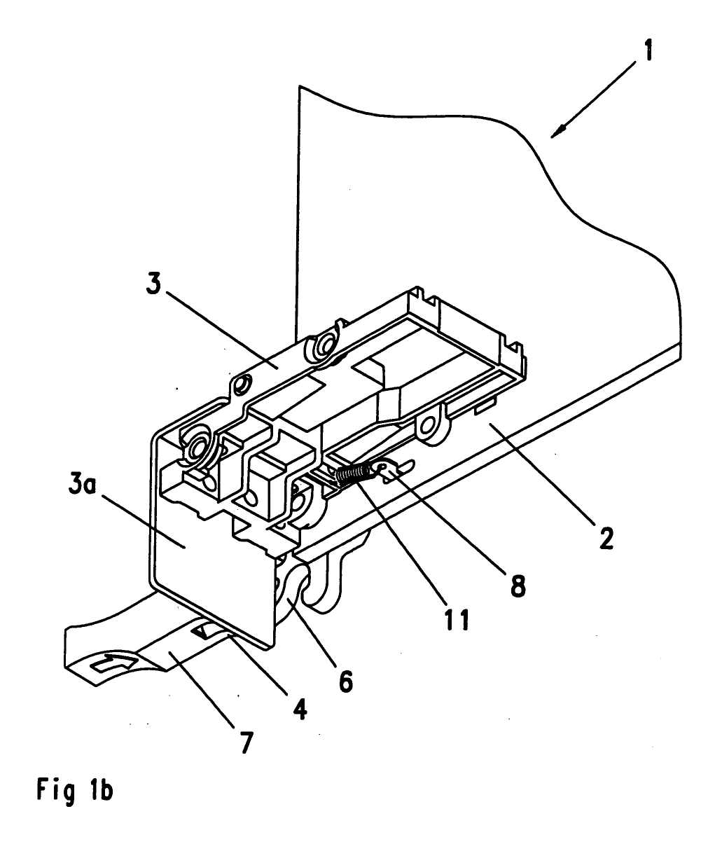

Referring to FIGS. 1a and 1b, there is shown perspective views of the front, lower corner region of an electronic plug-in unit 1, provided with a circuit board 2 on which electronic components are arranged. A corner piece 3, also called a brace or strut, is screwed to the circuit board 2. The corner piece 3 supports a short partial front panel 3a. A complete pull lever 4 is attached by a bearing screw 5 to the corner piece 3 and can be pivoted around an axis, lateral to the circuit board 2. A non-visible upper corner of the plug-in unit 1 has a mirror-image design.

The pull lever 4 essentially comprises two moving parts, namely a lever 6 and a handle 7 that is positioned on the lever 6, such that it can rotate and is displaceable in longitudinal direction. A push rod 8, angled multiple times, is positioned to be displaceable in the longitudinal direction. Push rod 8 is slidably fastened on the side, in front by a bearing screw 5 together with the lever 6, and in back by a second bearing screw 9. The push rod 8 can be displaced toward the back by pushing the handle 7 in the direction marked by the arrow, so as to activate a micro-switch 10 that is arranged in the region of the back end of the push rod 8. This micro-switch 10 functions to switch on or off the power supply for the plug-in unit. A tension spring 11 (see FIG. 1b) pulls the push rod 8 toward the front and toward the handle 7.

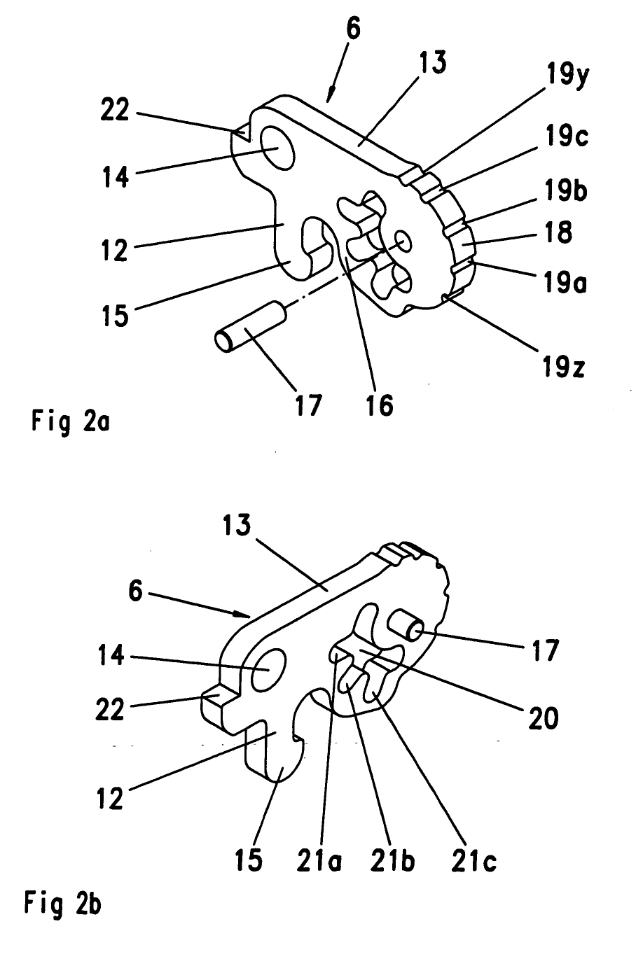

FIGS. 2a and 2b show only the lever 6 for the pull lever 4, wherein FIG. 2a shows a view at an angle from the front, corresponding to the viewing angle in FIG. 1a, while FIG. 2b shows the view at an angle from the back. The lever 6 may be produced as a one-piece metal die cast part. The lever 6 in principle has an L-shaped form, wherein a short leg of the L forms a short lever arm 12 and the long leg of the L forms a long lever arm 13. The point of intersection for the two legs contains a bearing bore 14. A nose or projectio 15 for levering-in/levering-out is formed onto the short lever arm 12 and is located opposite a curved push-back shoulder 16. A bearing shaft 17 is inserted at some distance to the exposed end of the long lever arm 13 and extends parallel to the bearing bore 14. The exposed end of the long lever arm 13 has a semi-circular contour with the bearing shaft 17 as the center point and forms a sliding surface 18 across which three engagement grooves 19a, 19b, 19c and two additional outer engagement grooves 19y, 19z are distributed. A circular slot 20, provided on the other side of the bearing shaft 17 relative to sliding surface 18, extends centrally around the bearing shaft 17 but at a shorter distance from shaft 17 than surface 18. Three radial slots 21a, 21b, 21c extend outward at the same distance to each other from the circular slot 20, wherein these are aligned radial to the bearing shaft 17. The circular slot 20 and the radial slots 21a, 21b, 21c form a rocking-arm guide. A projection with a horizontal stop surface 22 is formed on lever 6 in the area of the bearing bore 14.

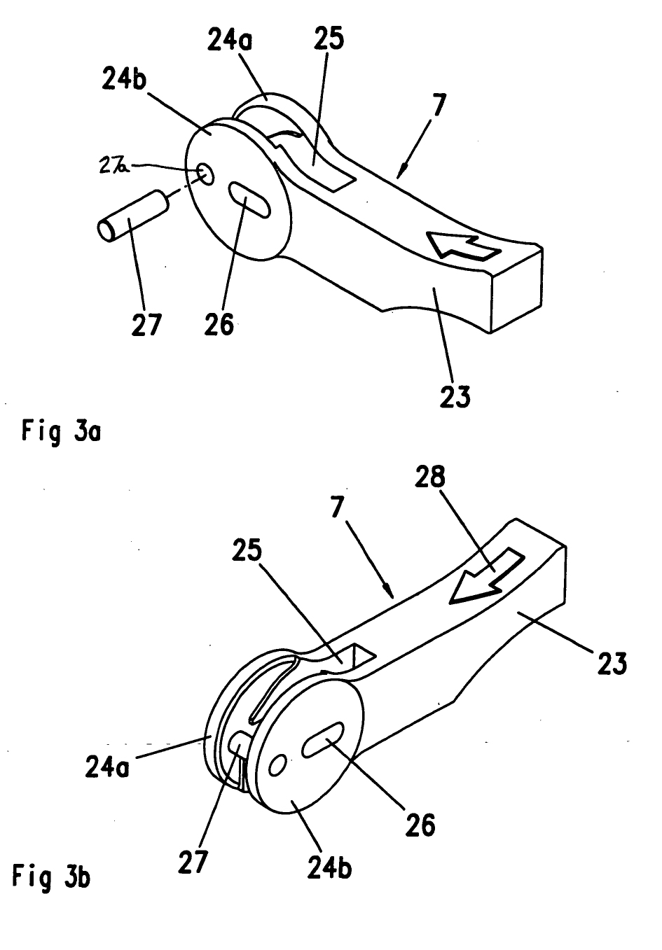

The handle 7 is shown prominently in FIGS. 3a and 3b, wherein it is shown in FIG. 3a with the same viewing angle as in FIG. 1a, and in FIG. 3b at an angle from the back. The handle 7 may be an injection-molded plastic part, with the front end embodied as a grip 23. The other end is shaped like a fork and comprises two round side parts 24a and 24b, which enclose a holding slot 25. The side parts 24a, 24b each are provided with an elongated hole 26, the back end of which is positioned in the center of the circular side parts 24a, 24b and defines the rotational axis for the handle 7. A follower pin 27 is positioned in corresponding bores 27a provided in the side parts 24a, 24b. The arrow 28 indicates the direction in which the handle 7 can be displaced through pushing.

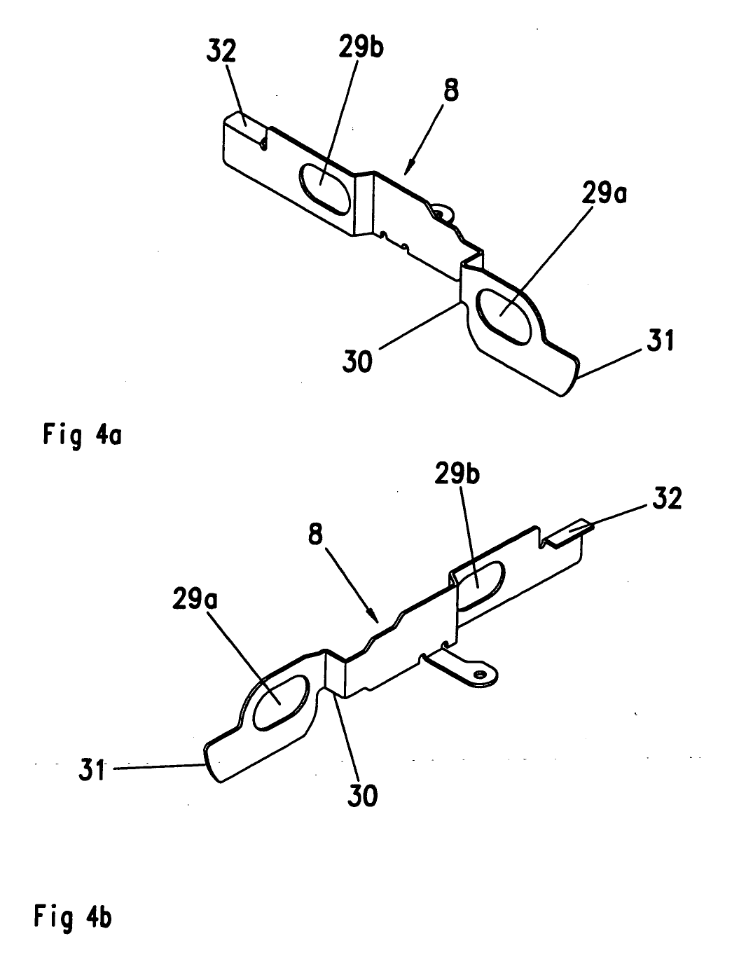

FIGS. 4a and 4b show the push rod 8 in further detail, wherein the viewing angle in FIG. 4a again corresponds to that in FIG. 1a and wherein FIG. 4b shows the push rod 8 from the back. The push rod 8 may be a metal part, produced by stamping it from thin sheet steel. An elongated hole 29a in the front and an elongated hole 29b in the back allow the displaceable positioning in the longitudinal direction on the corner piece 3 of the plug-in unit 1 with the aid of bearing screws 5 and 9 (compare FIG. 1a). The push rod 8 is angled twice in the center, in the shape of a Z, wherein the first, frontal angle forms a locking offset or stop shoulder 30. The front end is embodied as curved cam 31. A horizontal engagement surface 32 is embodied angling the back edge.

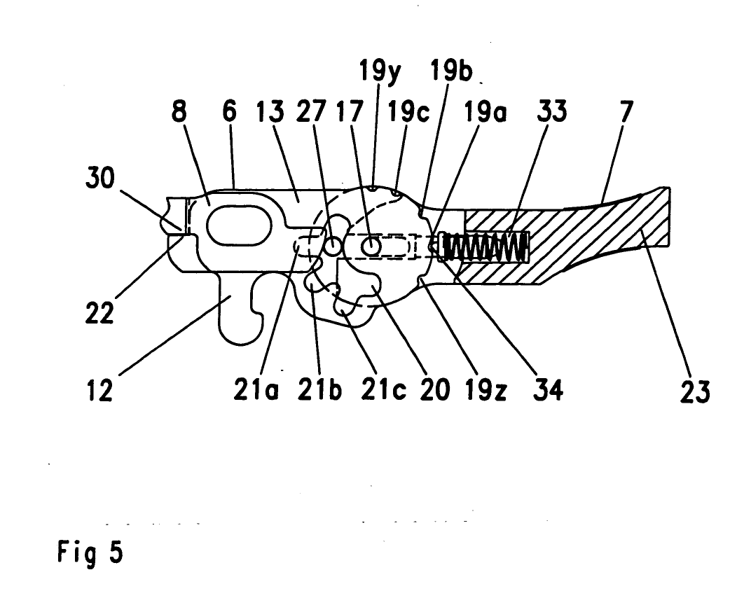

FIG. 5 clearly illustrates the functions of and the cooperation between the lever 6, the handle 7, and the push rod 8. The handle 7 is rotatably positioned on the long lever arm 13 of lever 6 and so that it can be displaced in the longitudinal direction by allowing the bearing shaft 17 of lever 6 to engage in the elongated hole 26 on the handle 7. In the exemplary case, the handle 7 is resting in the horizontal starting position. The bearing shaft 17 is located at the back (left) end of the elongated hole 26. The follower pin 27 of handle 7 can move freely along a circular path in the circular slot 20 of lever 6. A compression spring 33 is installed on the inside of handle 7, which pushes an engagement pin 34 against the sliding surface 18 on the exposed end of the long lever arm 13. The three engagement grooves 19a, 19b, 19c are assigned to the three radial slots 21a, 21b, 21, respectively, and are arranged in line with these.

In this way, the rotatable handle 7 can be secured in place in three angle positions, predetermined by the engagement grooves 19a, 19b, 19c, in which the follower pin 27 is positioned in front of one of the three radial slots 21a, 21b, 21c. The additional engagement grooves 19y and 19z are for the rest positions.

In FIG. 5, the push rod 8 is shown in its frontal end position, in which the stop surface 22 of lever 6 rests against the locking offset 30 on the push rod 8.

As a result, the lever 6 is locked and cannot be pivoted around its pivoting axis.

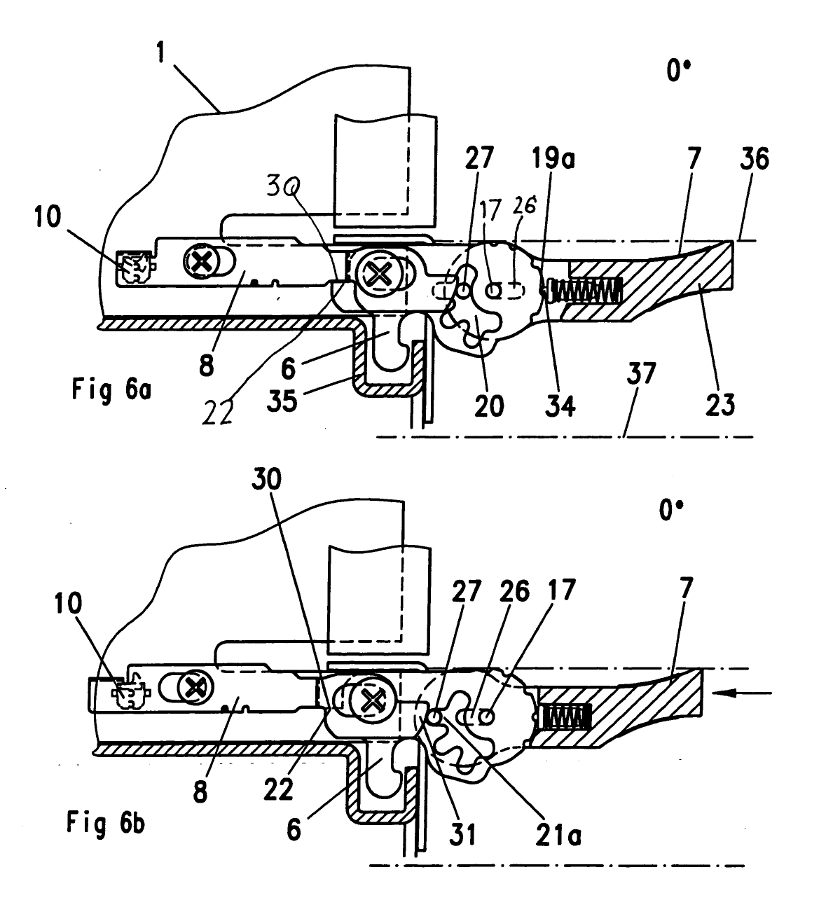

In the following, the additional Figures starting with FIG. 6a are used to explain how the plug-in unit 1 is removed with the aid of the pull lever 4 from a module carrier.

FIG. 6a shows the lower corner region of the plug-in unit 1, which is completely inserted into the module carrier, of which only the U-shaped profile of a lateral profile support 35 in front can be seen. A horizontal upper limiting line 36 and a lower limiting line 37, parallel thereto, delimit the clearance space inside of which the pull lever 4 can move. The lever 6 is in its horizontal rest position (0°). The handle 7 is also in the horizontal angle position, the normal position for installing a sub-module into the plug-in unit 1, directly below the upper limiting line 36, wherein the handle 7 is in its starting position relative to the lever 6. The bearing shaft 17 is positioned in the back end of the elongated hole 26 (on the left in the drawing). The push rod 8 is pushed all the way toward the front (to the right in the drawing). The locking offset 30 on the push rod 8 rests against the stop surface 22 of lever 6, thereby locking the lever 6 in place. The engagement pin 34 is positioned inside the engagement groove 19a on the sliding surface 18, thereby securing the handle 7. The follower pin 27 is positioned inside the circular slot 20. The micro-switch 10 is in the ON position, meaning the plug-in unit 1 is activated.

In FIG. 6b, pressure was exerted in the direction of the arrow onto the end of handle grip 23. As a result, the handle 7 is displaced in the longitudinal direction from the starting position to the engaged position while the horizontal angle position remains unchanged. The bearing shaft 17 has moved over to the front end (to the right in the drawing) of the elongated hole 26. At the same time, the follower pin 27 has been pushed into the upper radial slot 21a until it reaches the end stop. The handle 7 is then connected form-locking with the lever 6 and rotational forces introduced into the handle 7 are transferred to the lever 6. At the same time, the follower pin 27 exerts pressure onto the cam 31 and displaces the push rod 8 toward the back (on the left in the drawing). In this unlocked position of the push rod 8, the locking offset 30 has separated from the stop surface 22, so that the lever 6 is now released. The micro-switch 10 is then in the OFF position, meaning the power to the plug-in unit 1 has already been cut off.

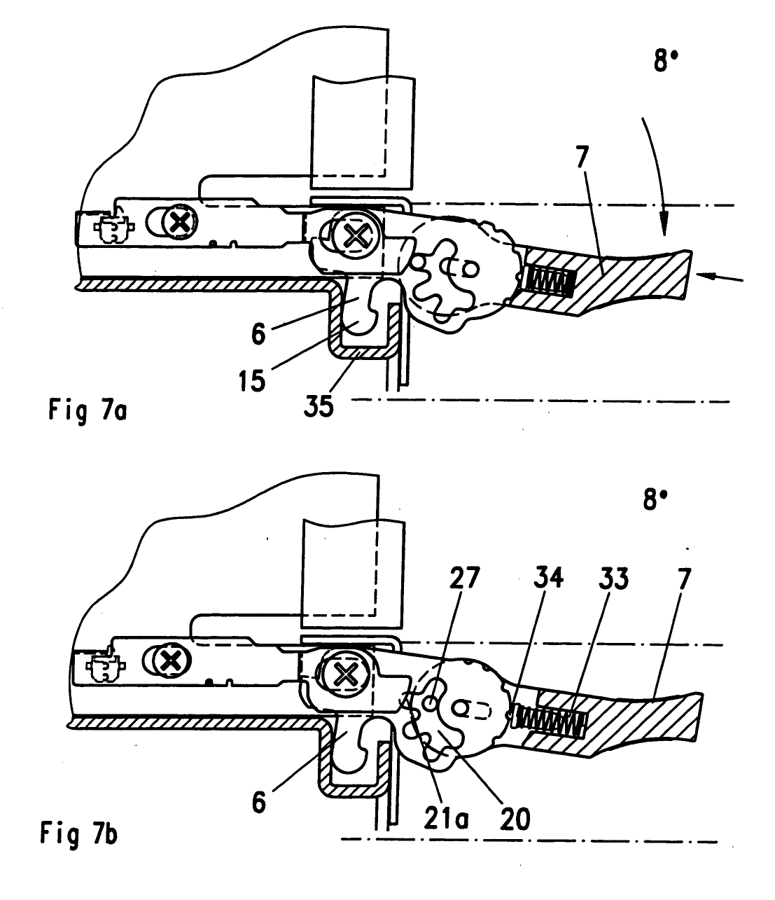

FIG. 7a shows the handle 7 and the lever 6, connected form-locking thereto, in a position where it is pivoted by 8° relative to the horizontal line. The levering-out nose 15 in this case rests against the lateral profile 35 and supports itself against its rear wall.

The angle position for lever 6 remains unchanged at 8° in the FIG. 7b. The handle 7 was released and has returned to its starting position under the effect of the compression spring 33, thereby allowing the follower pin 27 to slide out of the upper radial slot 21a and back into the circular slot 20. As a result, the form-locking connection between handle 7 and lever 6 no longer exists, wherein only the engagement pin 34 that is acted upon by the compression spring 33 prevents the handle 7 from leaving its horizontal angle position relative to the lever 6. The stop surface 22 of lever 6 has moved upward, relative to the locking offset 30 on the push rod 8, so that the push rod 8 can no longer snap back.

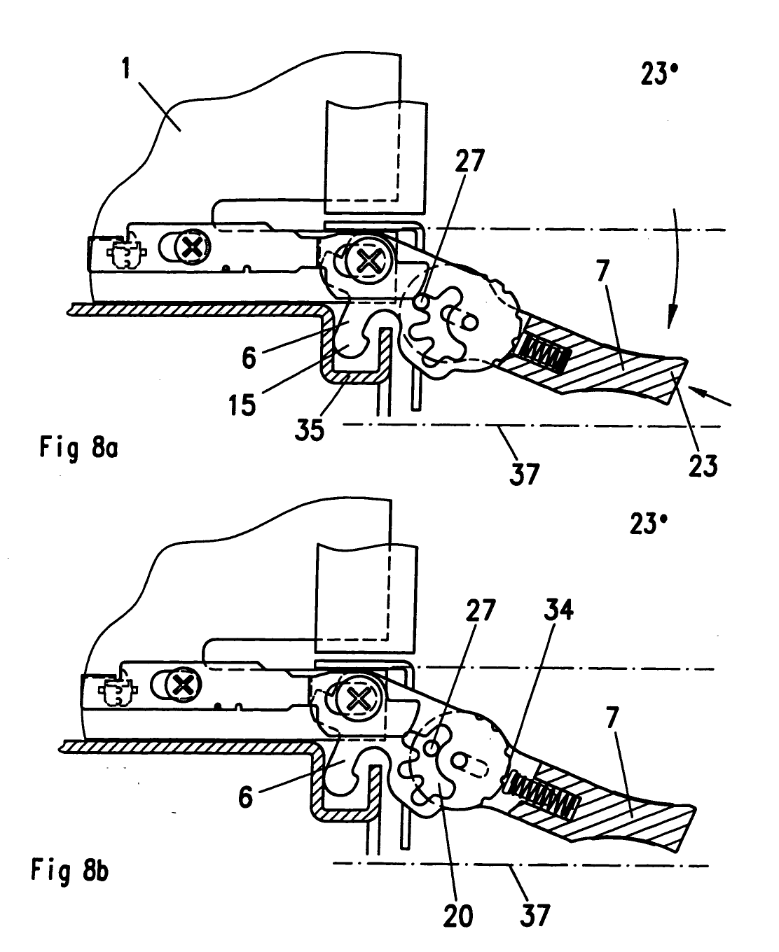

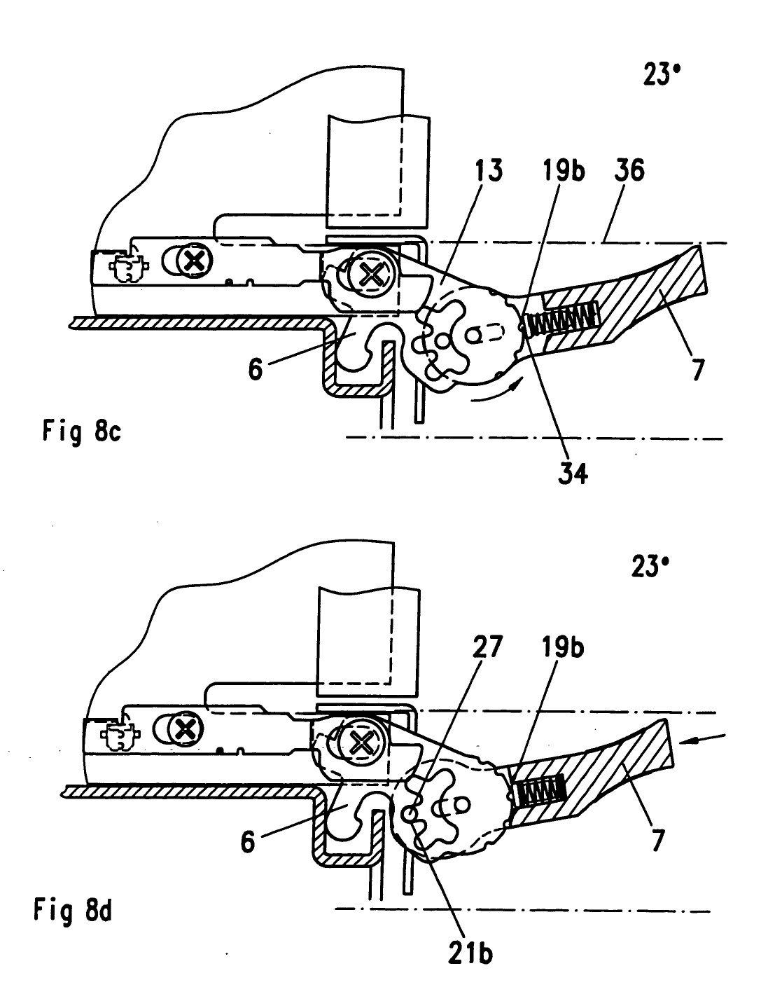

A renewed pressure onto the end of the gripping piece 23 returns the handle 7 to its form-locking connection with the lever 6. If the handle 7 is subsequently pivoted downward in the direction of the curved part, as shown in FIG. 8a, then the rotational force is transmitted via the engaged follower pin 27 to the lever 6 which is then pivoted in the same rotational direction. As a result of the levering-out nose 15 being supported on the lateral profile 35, the plug-in unit 1 starts to separate from its plug-in location in the module carrier and to move forward (to the right in the drawing).

Following a pivoting of the lever 6 by approximately 23°, relative to the horizontal line, the end of the handle grip 23 is moved close to the lower boundary line 37. If the pivoting movement were to be continued past the position shown in FIG. 8a, the lower boundary line 37 would be breached. Instead, the handle 7 returns from its engaged position, in which it is connected force-locking and form-locking with the lever 6, to its starting position, as shown in FIG. 8b. The follower pin 27 is thus again positioned inside the circular slot 20. From its angle position, which is secured only loosely by the engagement pin 34, the handle 7 can then be pivoted counter to the earlier pivoting direction, meaning toward the top.

FIG. 8c shows the handle 7, pivoted back by 33.5°, while the pivoting angle of 23° for the lever 6 remains unchanged. The handle 7 thus for the first time is positioned upward at an angle, relative to the long lever arm 13. The handle 7 hits the upper boundary line 36 with its extreme upper edge, and the engagement pin 34 is now fitted into the center engagement groove 19b.

In the next step, illustrated with FIG. 8d, the handle 7 is again connected form-locking with the lever 6. The follower pin 27, however, has moved into the center radial slot 21b that corresponds to the center engagement groove 19b.

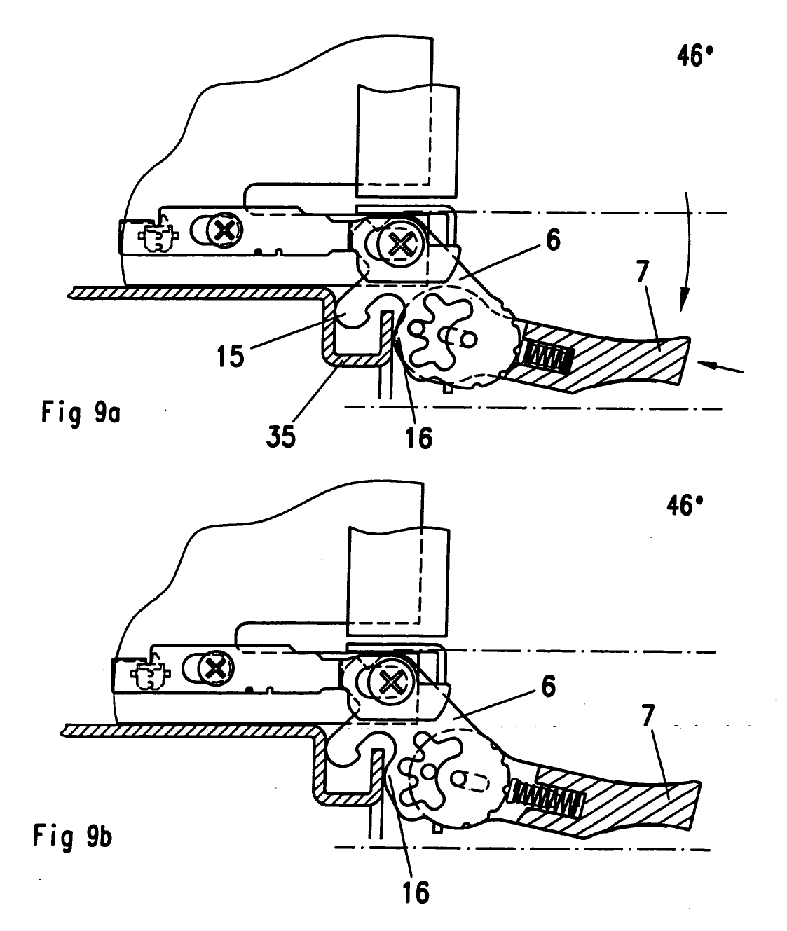

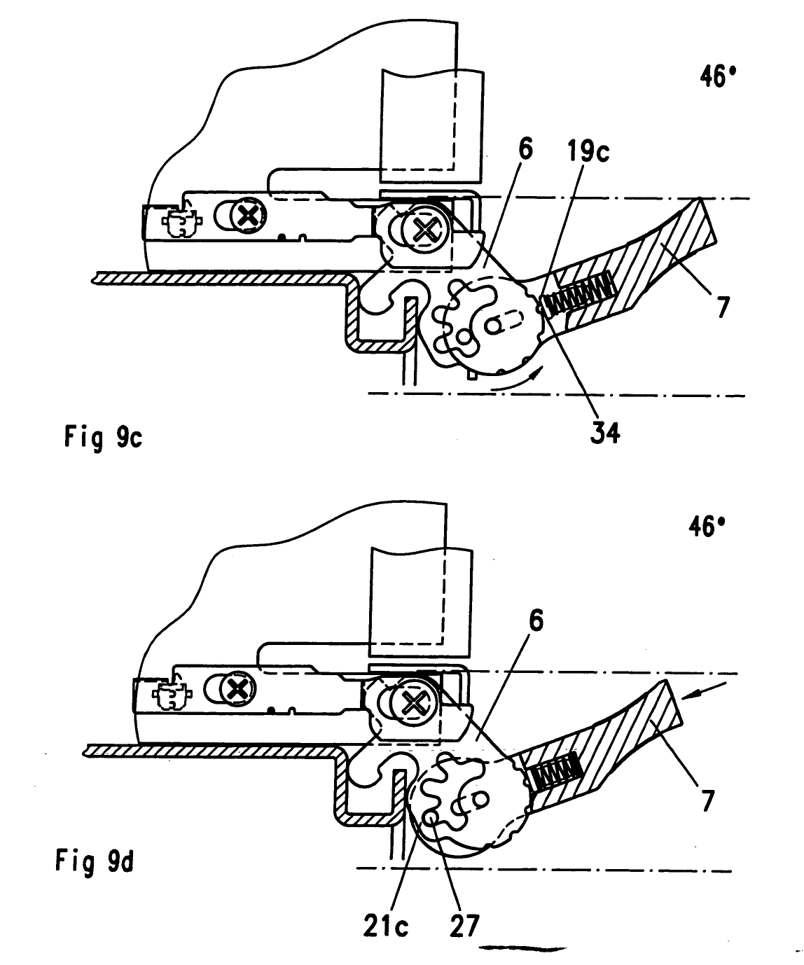

Following a second pushing down of the handle 7, the lever 6 reaches the position shown in FIG. 9a where it is pivoted by 46°, relative to the horizontal line. The levering-out nose 15 has worked its way upward in the lateral profile 35, wherein the levering out operation is aided by the push-back shoulder 16. At the same time, the plug-in unit 1 has moved forward again (to the right in the drawing).

In FIG. 9b, the compression spring 33 has returned the handle 7 to the starting position in which the handle 7 can rotate freely relative to the lever 6.

The handle 7 can then be reversed for the second time, meaning it can be turned back, until it reaches the angle position shown in FIG. 9c where the engagement pin 34 engages in the engagement groove 19c and the handle 7 is subsequently again connected form-locking with the lever 6. The follower pin 27 in this case engages in the third and lowest radial slot 21c.

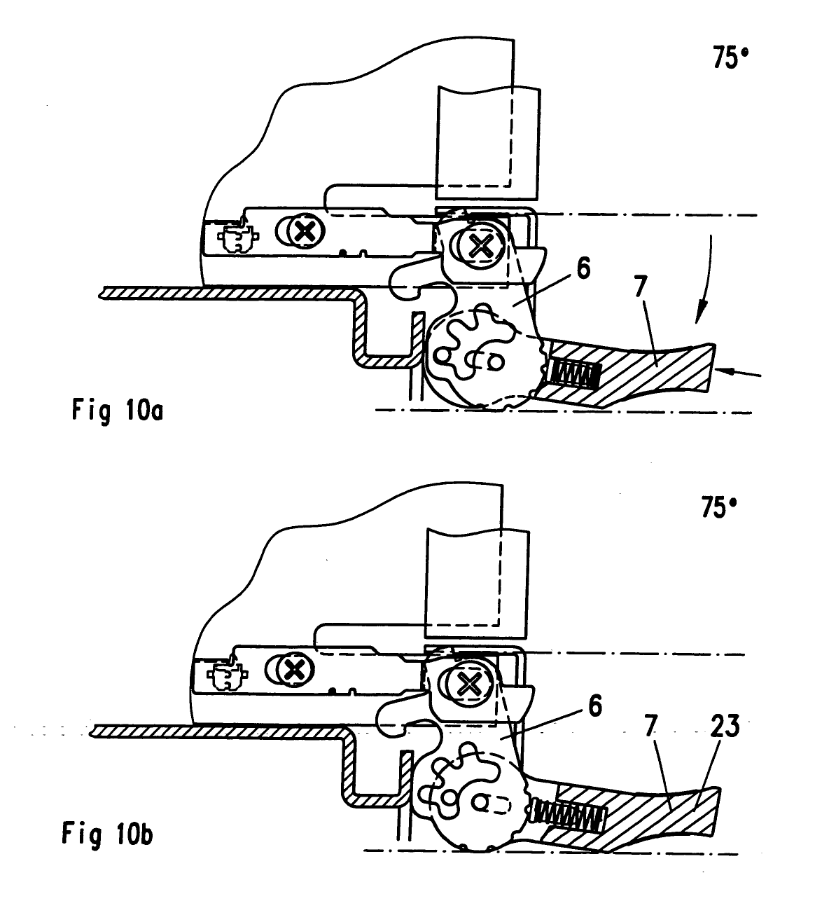

The handle 7 can be pushed downward for the third time, until it assumes the position shown in FIG. 10a. The lever 6 is then pivoted maximally, meaning by 75°, and the plug-in unit 1 is completely levered out.

The handle grip 23 is the last to be released, thus causing the handle 7 to lose the form-locking connection with the lever 6 and return to the starting position.

The handle 7 could then still be turned to an optional angle position, for example it could be tilted upward so that it won't be in the way.

The levering-in of the plug-in unit 1 occurs basically in the same way, just in the reverse sequence.

The invention has been described in detail with respect to preferred embodiments, and it will now be apparent from the foregoing to those skilled in the art, that changes and modifications may be made without departing from the invention in its broader aspects, and the invention, therefore, as defined in the appended claims, is intended to cover all such changes and modifications that fall within the true spirit of the invention.

What is claimed is:

1. A device for levering in and levering out a plug-in unit into and out of a module carrier, said device comprising:
a corner piece adapted for being arranged in a frontal region of the plug-in unit; and
a pull lever comprising:
a lever positioned to be pivotable on the corner piece, the lever including a long lever arm and a short lever arm that is adapted to be supported on a lateral profile of the module carrier, and
a handle rotatably positioned on the long lever arm of the lever;
wherein the handle is arranged to be displaceable in a longitudinal direction between a starting position in which the handle is freely rotatable, and an engaged position in which the handle is connected force-locking with the long lever arm for pivoting the lever.

2. The device as defined in claim 1, wherein the handle is force-lockingly connected with the long lever arm only in selected angle positions.

3. The device as defined in claim 1, wherein the handle includes an elongated hole and the long lever arm has a bearing shaft that engages in the elongated hole of the handle.

4. The device as defined in claim 1, further including a compression spring arranged to hold the handle in the starting position.

5. The device as defined in claim 1, wherein the form-locking connection includes corresponding components on the handle and the long lever arm.

6. The device as defined in claim 5, wherein the corresponding component on the handle includes a follower pin and the corresponding component on the long lever arm comprises a rocking-arm guide in which the follower pin of the handle engages.

7. The device as defined in one of the claims 2, further including engagement parts disposed on the long lever arm and the handle that cooperate with one another to secure the handle in predetermined angle positions.

8. The device as defined in claim 7, wherein the predetermined angle positions that are secured with the engagement parts correspond to the selected angle positions in which the handle is connected force-lockingly with the lever arm.

9. The device as defined in claim 2, further including a push rod positioned on the corner piece for displacement in a longitudinal direction, the push rod securing the lever against pivoting in a locked position and being displaceable from the locked position to an unlocked position by the handle when the handle is positioned in one of the specifically selected angle positions.

10. The device as defined in claim 9, wherein the plug-in unit includes a micro-switch and the push rod is arranged to activate the micro-switch to switch on a power supply for the plug-in unit.

11. The device as defined in claim 9, further including a tension spring arranged to pull the push rod in a direction of a front panel of the plug-in unit.
